(19) United States
(12) Patent Application Publication
(10) Pub. No.: US 2015/0017784 A1
(43) Pub. Date: Jan. 15, 2015

(54) SEMICONDUCTOR PROCESSING APPARATUS USING LASER

(71) Applicant: Samsung Electronics Co., Ltd., Suwon-si (KR)

(72) Inventor: Jong-guw KIM, Asan-si (KR)

(73) Assignee: SAMSUNG ELECTRONICS CO., LTD., Suwon-si (KR)

(21) Appl. No.: 14/330,055

(22) Filed: Jul. 14, 2014

(30) Foreign Application Priority Data
Jul. 15, 2013 (KR) 10-2013-0083105

(51) Int. Cl. H01L 21/268; B23K 26/40; B23K 26/067; B23K 26/08; B23K 26/06

(52) U.S. Cl. CPC H01L 21/268; B23K 26/0807; B23K 26/0648; B23K 26/067; B23K 26/4075
USPC 438/463; 219/121.75

(57) ABSTRACT

Provided is a semiconductor processing apparatus, including a first laser beam irradiation unit having a first variable beam expanding telescope and a first galvanometer scanner transferring a first laser beam having a first wavelength, a second laser beam irradiation unit having a second variable beam expanding telescope and a second galvanometer scanner transferring a second laser beam having a second wavelength, and a telecentric lens.

### CROSS-REFERENCE TO RELATED APPLICATIONS

This application claims the benefit of priority under 35 U.S.C. §119 to Korean Patent Application No. 10-2013-0083105 filed on Jul. 15, 2013, the disclosure of which is hereby incorporated by reference in its entirety.

### BACKGROUND

1. Field

Embodiments of the present general inventive concept relate to a semiconductor processing apparatus using a laser.

2. Description of the Related Art

In the past, in drilling and sawing a semiconductor package, a mechanical drilling method using physical contact or a mechanical sawing method using physical contact such as blade sawing has been used. However, there are concerns regarding such mechanical drilling or a sawing methods causing chipping, cracks or the like during processing of the substrate.

### SUMMARY

Embodiments of the present general inventive concept provide a semiconductor processing apparatus capable of improving productivity and reducing process maintenance infra costs.

Embodiments of the inventive concept also provide a semiconductor processing apparatus capable of performing a drilling process and a sawing (cutting) process using a laser at the same time.

Additional features and utilities of the present general inventive concept will be set forth in part in the description which follows and, in part, will be obvious from the description, or may be learned by practice of the general inventive concept.

The foregoing and/or other features and utilities of the present general inventive concept may be achieved by providing a semiconductor processing apparatus, including a first laser beam irradiation unit having a first variable beam expanding telescope and a first galvanometer scanner transferring a first laser beam having a first wavelength, a second laser beam irradiation unit having a second variable beam expanding telescope and a second galvanometer scanner transferring a second laser beam having a second wavelength, and a telecentric lens.

The telecentric lens may include a first telecentric lens configured to receive the first laser beam from the first laser irradiation unit and a second telecentric lens configured to receive the second laser beam from the second laser irradiation unit.

Each of the first telecentric lens and the second telecentric lens may include a diameter aperture, a concave lens, an aspherical lens, and a convex lens.

The first laser beam may have a wavelength of the infrared ray area band.

The second laser beam may have a wavelength of a visible ray area band.

The first galvanometer scanner may include a first X-direction galvanometer scanner configured to scan with the first laser beam in an X-direction and a first Y-direction galvanometer scanner configured to scan with the first laser beam in a Y-direction.

The second galvanometer scanner may include a second X-direction galvanometer scanner configured to scan with the second laser beam in an X-direction and a second Y-direction galvanometer scanner configured to scan with the second laser beam in a Y-direction.

The first galvanometer scanner may scan with the first laser beam in a circle or spiral shape.

The second galvanometer scanner may scan with the second laser beam in a line shape.

The apparatus may further include a laser oscillator configured to generate an initial laser beam and a laser wavelength converter configured to separate the initial laser beam into the first laser beam and the second laser beam.

One of the first laser beam and the second laser beam may have the same wavelength as the initial laser beam.

The first variable beam expanding telescope and second variable beam expanding telescope may include a divergence lens and a convergence lens, respectively.

The present general inventive concept may also provide a semiconductor processing method, including generating a laser beam having a visible ray area band and a laser beam having an infrared ray area band, expanding spot diameters of the laser beams, moving the laser beam having the visible ray area band linearly to cut a semiconductor substrate and moving the laser beam having the infrared ray area band rotationally to drill holes in a molding material on the semiconductor substrate without penetrating the semiconductor substrate, thereby performing a cutting process with the laser beam having the visible ray area band and performing a drilling process with the laser beam having the infrared ray area band, and the cutting process and the drilling process are performed at the same time.

The laser beam having the visible ray area band and the laser beam having the infrared ray area band may be radiated in parallel to optical axes thereof.

The laser beam having the visible ray area band may have a wavelength of about 532 nm and the laser beam having the infrared ray area band may have a wavelength of about 1064 nm.

The present general inventive concept may also provide a semiconductor processing apparatus, including a first laser beam irradiation unit configured to control a spot position of a first laser beam having a first wavelength, a second laser beam irradiation unit configured to control a spot position of a second laser beam having a second wavelength, and at least one telecentric lens configured to control travel directions of the first and second laser beams to be parallel to optical axes of the first and second laser beams.

The first and second irradiation units each may include at least two galvanometer scanners configured to move the respective spot positions of the first and second laser beams in at least two directions.

The at least one telecentric lens may include a first telecentric lens configured to control the travel directions of the first laser beam and a second telecentric lens configured to control the travel direction of the second laser beam.

The first and second irradiation units may include a first and second variable beam expanding telescope, respectively, configured to control a spot diameter size of the first and second laser beams.

The present general inventive concept may also provide a method of processing a semiconductor package including scanning a first laser beam having a first wavelength in at least one straight line direction to cut a semiconductor substrate, and scanning a second laser beam having a second wavelength in a circular direction to drill a plurality of holes in a molding material on the semiconductor substrate without penetrating the semiconductor substrate.

At least one of the plurality of holes may be formed to have a tapered inner wall in which a diameter of an upper portion is larger than a diameter of a lower portion.

A scanning speed to scan the first and second laser beams may be between 300 to 1200 mm/sec.

The first and second laser beams may be generated at a power level between 5 to 30 W.

### BRIEF DESCRIPTION OF THE DRAWINGS

These and/or other features and utilities of the present general inventive concept will become apparent and more readily appreciated from the following description of the embodiments, taken in conjunction with the accompanying drawings of which:

FIG. 1A and FIG. 1B are exploded perspective views illustrating a semiconductor processing apparatus using a laser according to an exemplary embodiment of the present general inventive concept.

FIG. 2 is a view illustrating a laser oscillator according to an exemplary embodiment of the present general inventive concept.

FIG. 3 is a view illustrating a structure of an excitation chamber of a laser oscillator according to an exemplary embodiment of the present general inventive concept.

FIG. 4 is a view illustrating a laser wavelength converter according to an exemplary embodiment of the present general inventive concept.

FIG. 5 is a view illustrating a variable beam expanding telescope according to an exemplary embodiment of the present general inventive concept.

FIG. 6 is a view illustrating a galvanometer scanner according to an exemplary embodiment of the present general inventive concept.

FIG. 7 is a view illustrating a configuration of a telecentric lens according to an exemplary embodiment of the present general inventive concept.

FIG. 8 is view illustrating a process of irradiating a laser beam on the top of a semiconductor package in a semiconductor processing apparatus using a laser according to an exemplary embodiment of the present general inventive concept.

FIG. 9A to FIG. 9E are views illustrating performing a drilling process and a sawing process using a semiconductor processing apparatus using a laser according to an exemplary embodiment of the present general inventive concept.

### DESCRIPTION OF THE EMBODIMENTS

Reference will now be made in detail to the embodiments of the present general inventive concept, examples of which are illustrated in the accompanying drawings, wherein like reference numerals refer to the like elements throughout. The embodiments are described below in order to explain the present general inventive concept while referring to the figures. These inventive concepts may, however, be embodied in different forms and should not be construed as limited to the embodiments set forth herein. Rather, these embodiments are provided so that this disclosure is thorough and complete and fully conveys the inventive concept to those skilled in the art. In the drawings, the sizes and relative sizes of layers and regions may be exaggerated for clarity.

The matters defined in the description, such as detailed construction and elements, are provided to assist in a comprehensive understanding of the exemplary embodiments. Thus, it is apparent that the exemplary embodiments can be carried out without those specifically defined matters. Also, functions or elements known in the related art are not described in detail since they would obscure the exemplary embodiments with unnecessary detail.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive concept.

Spatially relative terms, such as “beneath,” “below,” “lower,” “above,” “upper” and the like, may be used herein for ease of description to describe one element's or feature's relationship to another elements or features as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments are described herein with reference to cross-sectional illustrations that are schematic illustrations of idealized embodiments (and intermediate structures). As such, variations from the shapes of the illustrations as a result, for example, of manufacturing techniques and/or tolerances, are to be expected. Thus, embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concept.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Further, the embodiments described in this specification will be explained with reference to sectional views and/or plan views which are ideal exemplary views.

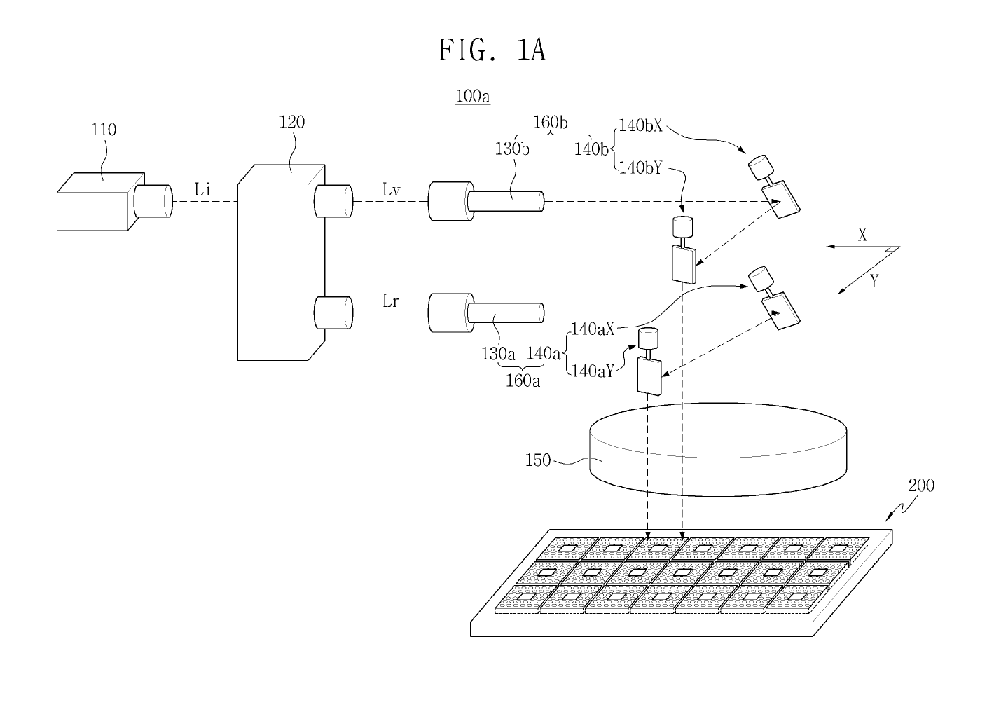

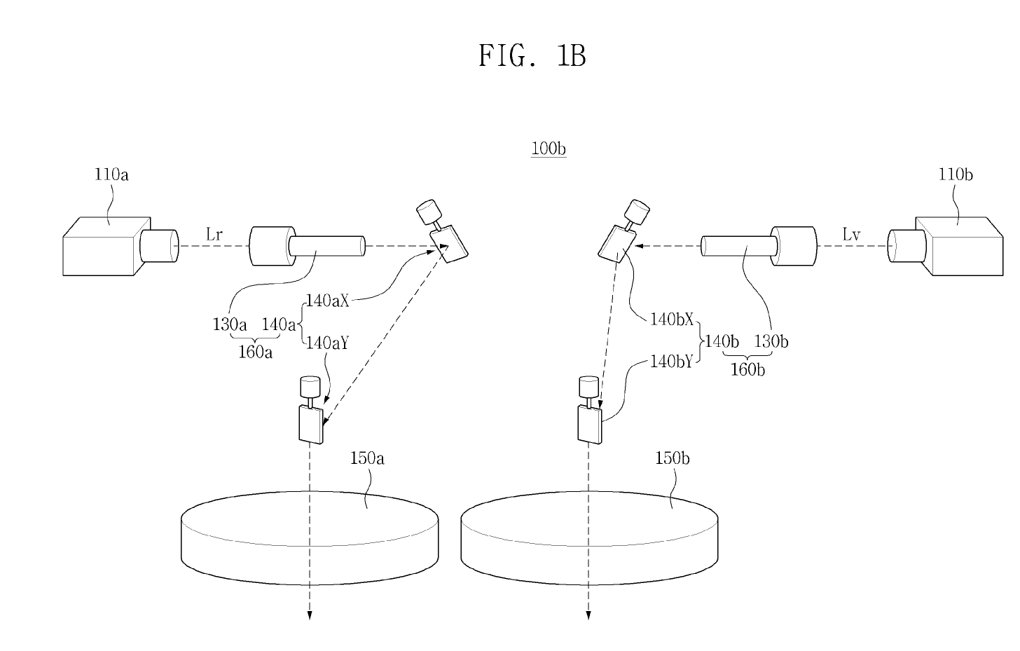

FIG. 1A is an exploded perspective view of a semiconductor processing apparatus using a laser according to an exemplary embodiment of the present general inventive concept.

Referring to FIG. 1A, the semiconductor processing apparatus 100a using the laser according to an exemplary embodiment of the present general inventive concept may include a laser oscillator 110, a laser wavelength convertor 120, a first laser beam irradiation unit 160a, a second laser beam irradiation unit 160b and a telecentric lens 150. Although two irradiation units 160a, 160b are illustrated in FIG. 1A the present general inventive concept is not limited thereto and additional laser oscillators 110, laser wavelength convertors 120 and irradiation units 160a, 160b may be included. Furthermore, multiple laser oscillators may be used to increase laser power.

The first laser beam irradiation unit 160a may include a first variable beam expanding telescope 130a and a first galvanometer scanner 140a.

The second laser beam irradiation unit 160b may include a second variable beam expanding telescope 130b and a second galvanometer scanner 140b.

The laser oscillator 110 may generate a laser beam Li.

The laser wavelength convertor 120 may separate the laser beam Li having a single wavelength into two laser beams Lv and Lr having differing wavelengths, for example, the laser beam Lr of an infrared ray area band and the laser beam Lv of a visible ray area band, and output both the Lr and Lv laser beams (as illustrated in FIG. 4).

The first variable beam expanding telescope 130a and the second variable beam expanding telescope 130b may control spot diameters of the laser beams Lr and Lv output from the laser wavelength convertor 120, respectively. For example, the first variable beam expanding telescope 130a may control the spot diameter of the laser beam Lr of the infrared ray area band and the second variable beam expanding telescope 130b may control the spot diameter of the laser beam Lv of the visible ray area band.

The first galvanometer scanner 140a may control an irradiation position of the laser beam Lr of an infrared ray area band and the second galvanometer scanner 140b may control an irradiation position of the laser beam Lv of the visible ray area band.

The first galvanometer scanner 140a may include a first X-direction galvanometer scanner 140aX capable of scanning a semiconductor package 200 with the laser beam Lr of the infrared ray area band in the X-direction and a first Y-direction galvanometer scanner 140aY capable of scanning the semiconductor package 200 with the laser beam Lr in the Y-direction.

The second galvanometer scanner 140b may include a second X-direction galvanometer scanner 140bX capable of scanning the semiconductor package 200 with the laser beam Lv of the visible ray area band in the X-direction and a second Y-direction galvanometer scanner 140bY capable of scanning the semiconductor package 200 with the laser beam Lv in the Y-direction.

The first X-direction galvanometer scanner 140aX and the first Y-direction galvanometer scanner 140aY may be positioned to be compatible with each other, and the second X-direction galvanometer scanner 140bX and the second Y-direction galvanometer scanner 140bY may be positioned to be compatible with each other.

The laser beam Lr of the infrared ray area band may be incident on the first X-direction galvanometer scanner 140aX, and then may be reflected to the first Y-direction galvanometer scanner 140aY. The laser beam Lv of the visible ray area band may be incident on the second X-direction galvanometer scanner 140bX, and then may be reflected to the second Y-direction galvanometer scanner 140bY.

The laser beam Lr of the infrared ray area band, which is incident on the first Y-direction galvanometer scanner 140aY, and the laser beam Lv of the visible ray area band, which is incident on the second Y-direction galvanometer scanner 140bY, may both be reflected to the telecentric lens 150.

The telecentric lens 150 may control travel directions of the laser beams Lr and Lv to be parallel to the optical axes of the laser beams Lr and Lv.

FIG. 1B is an exploded perspective view of a semiconductor processing apparatus 100b using a laser according to an exemplary embodiment of the present general inventive concept.

Referring to FIG. 1B, the semiconductor processing apparatus 100b using the laser according to an exemplary embodiment of the present general inventive concept may include first and second laser oscillators 110a and 110b, first and second laser beam irradiation units 160a and 160b and first and second telecentric lenses 150a and 150b. Although two irradiation units 160a, 160b are illustrated in FIG. 1B, the present general inventive concept is not limited thereto and additional laser oscillators 110a, 110b, telecentric lenses 150 and irradiation units 160a, 160b may be included. Furthermore, multiple laser oscillators may be used to increase laser power.

The first laser beam irradiation unit 160a may include a first variable beam expanding telescope 130a and a first galvanometer scanner 140a.

The second laser beam irradiation unit 160b may include a second variable beam expanding telescope 130b and a second galvanometer scanner 140b.

The first laser oscillator 110a may generate a laser beam Lr of the infrared ray area band and the second laser oscillator 110b may generate a laser beam Lv of the visible ray area band.

The spot diameters of laser beams Lr, Lv output from the first and second laser oscillators 110a and 110b may be controlled through the first and second variable beam expanding telescopes 130a and 130b, respectively.

The first galvanometer scanner 140a may include a first X-direction galvanometer scanner 140aX scanning a semiconductor package 200 with the laser beam Lr of the infrared ray area band in the X-direction and a first Y-direction galvanometer scanner 140aY scanning the semiconductor package 200 with the laser beam Lr in the Y-direction.

The second galvanometer scanner 140b may include a second X-direction galvanometer scanner 140bX scanning the semiconductor package 200 with the laser beam Lv of the visible ray area band in the X-direction and a second Y-direction galvanometer scanner 140bY scanning the semiconductor package 200 with the laser beam Lv in the Y-direction.

The laser beam Lr of the infrared ray area band may be incident on the first X-direction galvanometer scanner 140aX and reflected to the first Y-direction galvanometer scanner 140aY. The laser beam Lr of the infrared ray area band which is incident on the first Y-direction galvanometer scanner 140aY may be reflected to the first telecentric lens 150a. The laser beam Lv of the visible ray area band may be incident on the second X-direction galvanometer scanner 140bX and then reflected to the second Y-direction galvanometer scanner 140bY. The laser beam Lv of the visible ray area band which is incident on the second Y-direction galvanometer scanner 140bY may be reflected to the second telecentric lens 150b.

The first and second telecentric lenses 150a and 150b may be aligned with the first laser beam irradiation unit 160a and the second laser beam irradiation unit 160b, respectively.

The first and second telecentric lenses 150a and 150b may control the travel directions of the laser beam Lr of the infrared ray area band and the laser beam Lv of the visible ray area band to be parallel to their optical axes, respectively.

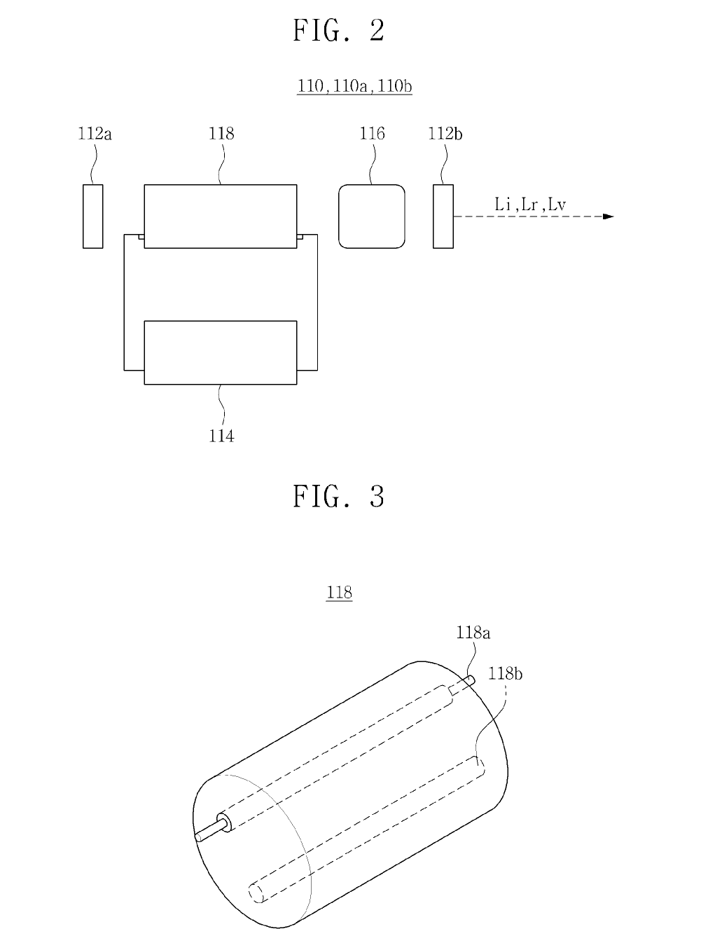

FIG. 2 is a view illustrating a structure of the laser oscillators 110, 110a and 110b according to an exemplary embodiment of the present general inventive concept.

Referring to FIG. 2, the laser oscillators 110, 110a and 110b may include a rear mirror 112a, a front mirror 112b, an external power source 114, a Q-switch 116 and an excitation chamber 118, respectively.

The rear mirror 112a may have a reflection rate which is approximately 100% and the front mirror 112b may have an arbitrary transmission rate. The front mirror 112b transmission rate may be related to whether the oscillator is used to generate a laser beam Lr of the infrared ray area band or a laser beam Lv of the visible ray area band.

The external power source 114 may supply power to generate light in the excitation chamber 118.

The excitation chamber 118 may amplify the light and generate the laser beam Li, Lr or LV. For example, the laser beams Li, Lr and Lv may be generated in such a manner that light repeatedly and reciprocally passes through the excitation chamber 118 between the rear mirror 112a and the front mirror 112b, and thus its intensity is amplified.

The Q-switch 116 may open a light path if the amplified intensity of the laser beams Li, Lr and Lv exceeds a threshold value, and thereby the laser beam Li, Lr or Lv may be output through the front mirror 112b. The Q-switch 116 may be controlled to adjust the output intensity of laser beams Li, Lr and Lv. Alternatively, the laser beams Li, Lr and Lv may be generated by using other methods without Q-switch 116, such as, for example, by a pulsed pumping operation.

FIG. 3 is a view illustrating a structure of the excitation chamber 118 of the laser oscillator 110 according to an exemplary embodiment of the present general inventive concept.

Referring to FIG. 3, the excitation chamber 118 may include a lamp 118a and an active medium 118b as an external stimulus element. The active medium 118b may be a solid medium, a liquid medium or a gas medium, for example. In the case of the solid medium, ruby, Nd:glass or an Nd:yttrium aluminum garnet (YAG) may be included. The lamp 118a may be, for example, an arc lamp, flashlamp or a laser diode. The laser beams having the same phase and wavelength may be emitted while electrons in the active medium 118b are excited by the lamp 118a and thereafter transit to a ground state. The intensity of the laser beams may be increasingly amplified while the emitted laser beams reciprocate in the active medium 118b. Different types of active medium 118b may be used to generate laser beams Li, Lr and Lv, respectively. For example, a first type of active medium 118b may be used to generate Lr and a second type of active medium 118b may be used to generate Lv.

FIG. 4 is a view illustrating the laser wavelength convertor 120 according to an exemplary embodiment of the present general inventive concept.

Referring to FIG. 4, the laser wavelength convertor 120 may include a non-linear unit 122 and a splitting unit 124.

The non-linear unit 122 may include a non-linear optical crystal. The non-linear optical crystal may include, for example, KTP (KTiOPO₄). The non-linear optical crystal may have a double refraction characteristic. If an initial laser beam Li is incident on the non-linear unit 122, one portion thereof may oscillate electrons in a horizontal direction with respect to the plane parallel to the initial laser beam Li and another portion may oscillate electrons in a perpendicular direction with respect to the plane parallel to the initial laser beam Li. The splitting unit 124 may separate the initial laser beam Li into a first laser beam L1 having the same wavelength as the initial laser beam Li and a second laser beam L2 in which the wavelength is converted and output both the first laser beam L1 and the second laser beam L2. Otherwise, the second laser beam L2 may have the same wavelength as the initial laser beam Li and the first laser beam L1 may have a different wavelength from the initial laser beam Li. For example, one of the first laser beam L1 and the second laser beam L2 may have the wavelength of the infrared ray area band of 1064 nm and the other one may have the wavelength of the visible ray area band of 532 nm.

The splitting unit 124 may split the laser beam Lr of the infrared ray area band and the laser beam Lv of the visible ray area band and then output both of them. The splitting unit 124 may include a first splitting mirror 124a that reflects the laser beam Lr of the infrared ray area band and penetrates the laser beam Lv of the visible ray area band and a second splitting mirror 124b that reflects the laser beam Lr of the infrared ray area band. Surfaces of the first and second splitting mirrors 124a and 124b may be coated with silver.

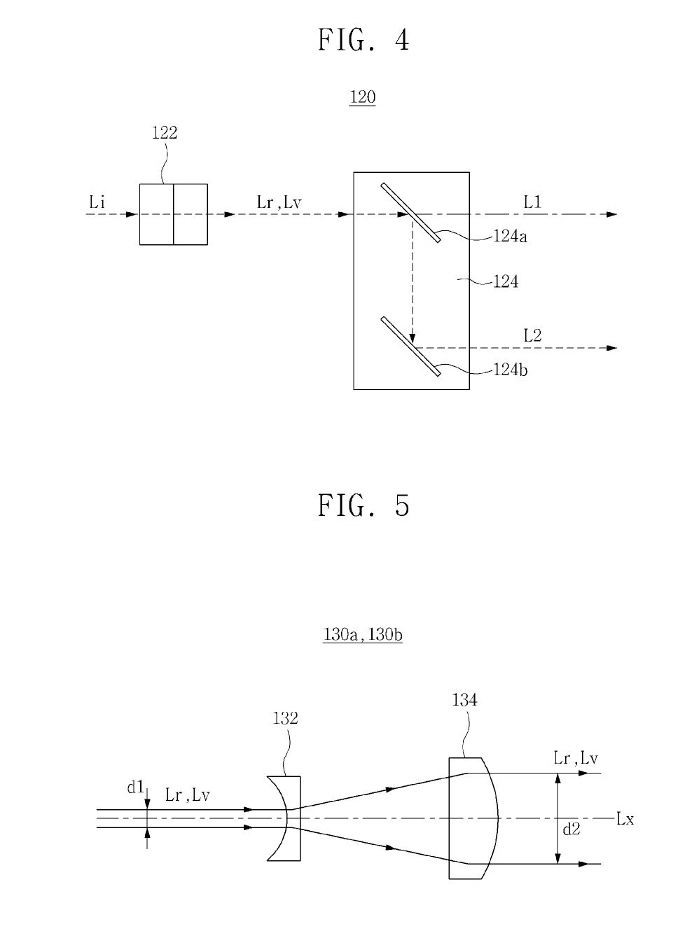

FIG. 5 is a view illustrating the first and second variable beam expanding telescopes 130a and 130b according to an exemplary embodiment of the present general inventive concept.

Referring to FIG. 5, the first and second variable beam expanding telescopes 130a and 130b may be similarly constructed, that is, each may include a divergence lens 132 that changes the incident laser beams Lr and Lv into a form of emission light and a convergence lens 134 that changes the laser beams Lr and Lv in the form of emission light into a form of parallel light. For example, the divergence lens 132 may include a concave lens, and the convergence lens 134 may include a convex lens. Laser beams Lr and Lv output from the convergence lens 134 may have a spot diameter d2 expanded across an optical axis Lx beyond a spot diameter d1 of the laser beams Lr and Lv which is incident on the divergence lens 132 (d1<d2).

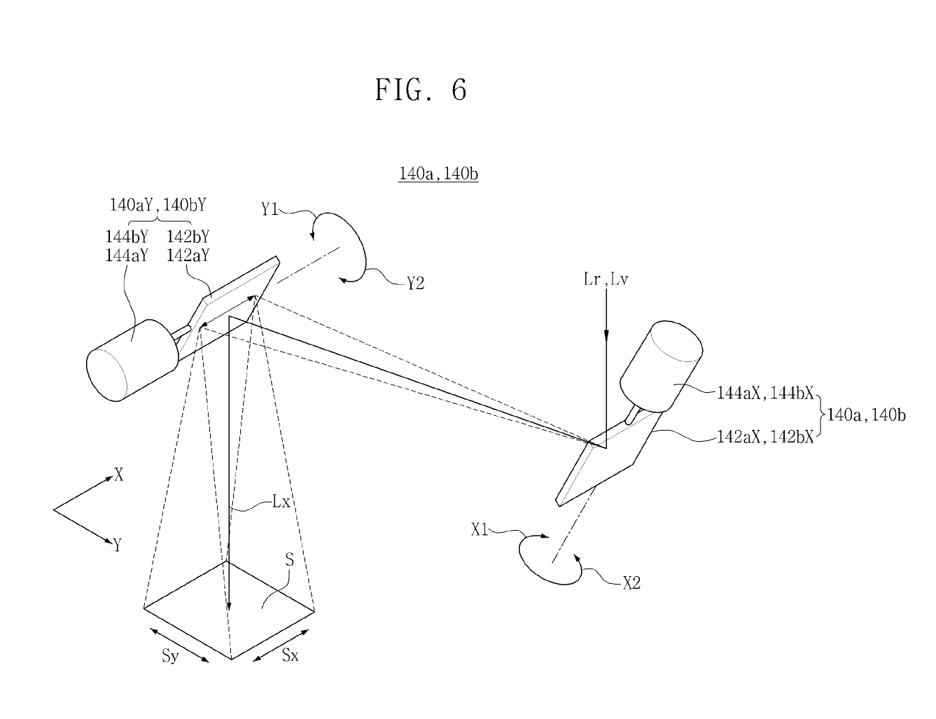

FIG. 6 is a view illustrating the first and second galvanometer scanners 140a and 140b according to an exemplary embodiment of the present general inventive concept.

Referring to FIG. 6, the first and second galvanometer scanners 140a and 140b may include the first and second X-direction galvanometer scanners 140aX and 140bX scanning a semiconductor package 200 with laser beams Lr and Lv in the X-direction and the first and second Y-direction galvanometer scanners 140aY and 140bY scanning a semiconductor package 200 with laser beams Lr and Lv in the Y-direction. The galvanometer scanners 140aX, 140aY, 140bX and 140bY may include mirrors 142aX, 142aY, 142bX and 142bY and driving sources 144aX, 144aY, 144bX and 144bY that rotate them, respectively. The driving sources 144aX, 144aY, 144bX and 144bY may rotate the mirrors 142aX, 142aY, 142bX and 142bY in the X1, X2, Y1 and/or Y2 directions, respectively, and may scan the semiconductor package 200 with laser beams Lr and Lv in a scan region S.

For example, laser beams Lr and Lv may be used to scan along the X-direction distance (Sx) by the first and second X-direction galvanometer scanners 140aX and 140bX and may reciprocally move along the Y-direction distance (Sy) by the first and second Y-direction galvanometer scanners 140aY and 140bY. The X-direction and the Y-direction may be perpendicular to the optical axes Lx of the laser beams Lr and Lv, respectively.

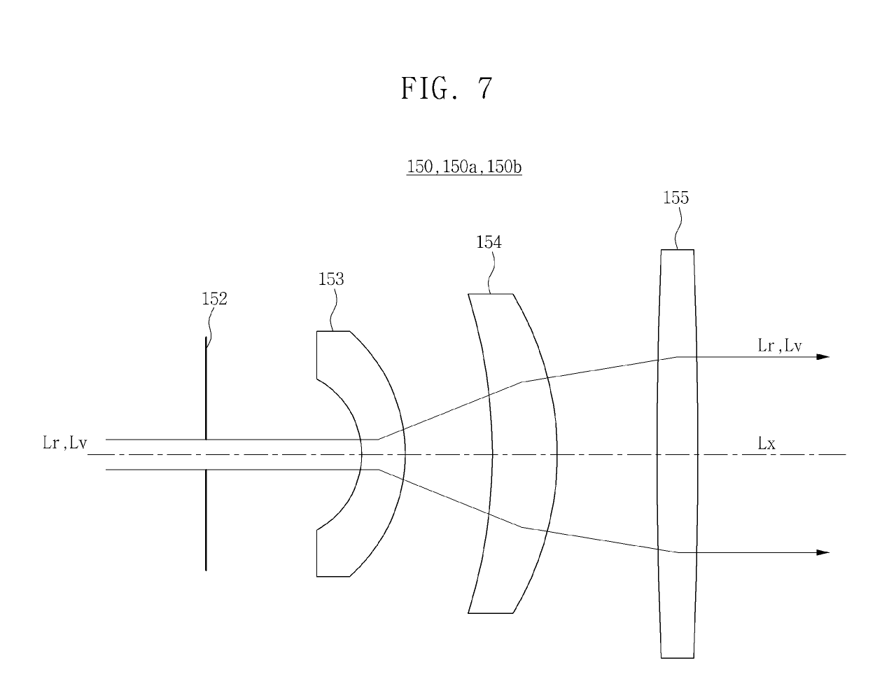

FIG. 7 is a view illustrating a construction of the telecentric lenses 150, 150a and 150b according to an exemplary embodiment of the present general inventive concept.

Referring to FIG. 7, the telecentric lenses 150, 150a and 150b may include a numerical aperture 152, a concave lens 153, an aspherical lens 154 and a convex lens 155. By controlling a diameter of the numerical aperture 152 and/or a distance between the numerical aperture 152 and the concave lens 153, the travel directions of the laser beams Lr and Lv passing through the concave lens 153, the aspherical lens 154 and the convex lens 155 in turn may be controlled to be parallel to the optical axis Lx.

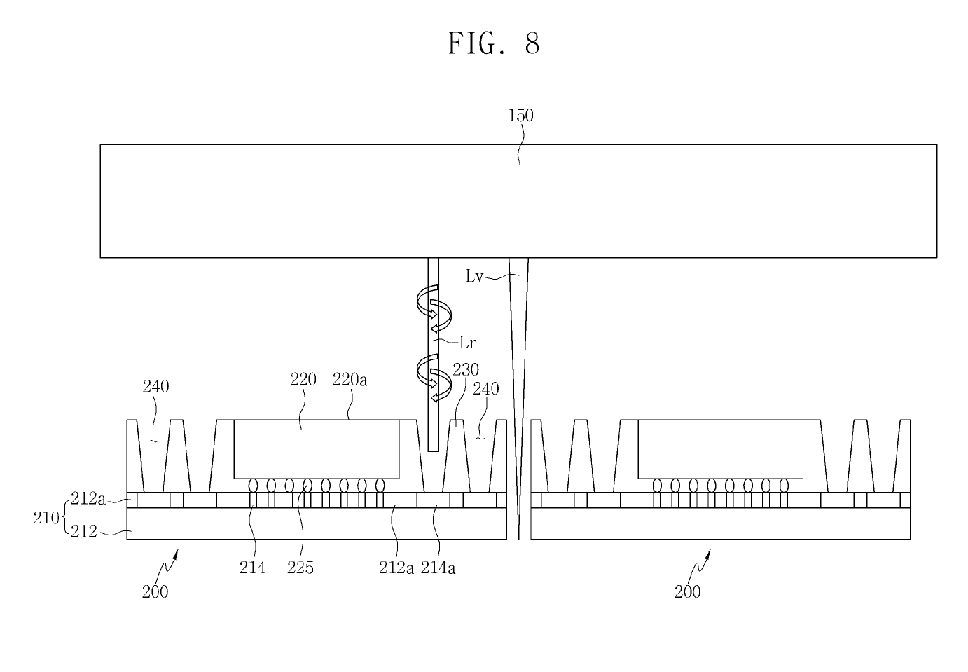

FIG. 8 is a view illustrating a process of irradiating a laser beam on the top of a semiconductor package 200 in the semiconductor processing apparatuses 100a or 100b using a laser according to an exemplary embodiment of the present general inventive concept.

Referring to FIG. 8, the semiconductor package 200 may include a substrate 210, a semiconductor chip 220 mounted on the substrate 210, a molding material 230 including a plurality of holes 240.

The substrate 210 may include a printed circuit board (PCB) for a package, for example. The substrate 210 is a substrate including a plurality of lower wires and may include, for example, a rigid printed circuit board, a flexible printed circuit board, or a rigid-flexible printed circuit board. On the top surface of the substrate 210, a plurality of chip bump lands 214 for electrically connecting the semiconductor chip 220 to other components may be disposed to be exposed. The substrate 210 may include a core layer 212 and a solder resist layer 212a. The plurality of lower wires may be disposed in the core layer 212.

On the top surface of the substrate 210, the upper lands 214a, insulated from each other by the solder resist layer 212a, may be disposed. The upper lands 214a may include, for example, Cu, Ni, Au or solder materials.

The semiconductor chip 220 may include logic elements such as a microprocessor, a microcontroller or an application processor (AP). The semiconductor chip 220 may be a system-on-chip in which various other kinds of semiconductor elements are combined together.

The semiconductor chip 220 may be electrically connected with the chip bump lands 214 which are exposed to the substrate 210 through chip bumps 225. The chip bumps 225 may include solder materials.

The molding material 230 may be formed to surround the semiconductor chip 220 and the chip bumps 225. The molding material 230 may be formed to expose the upper surface 220a of the semiconductor chip 220, and thereby the entire thicknesses of the semiconductor package 200 can be reduced. The molding material 230 may include an epoxy mold compound (EMC).

The plurality of holes 240 may each include a tapered inner wall in which a diameter of an upper portion is larger than a diameter of a lower portion. However, the plurality of holes 240 are not limited to this shape and may have other shapes, for example, a uniform diameter along their respective inner walls. Alternatively, the plurality of holes 240 may include a mixture of shapes.

The laser beam Lr of the infrared ray area band may perform a drilling process on the molding material 230 portion of the semiconductor package 200 after passing through the telecentric lens 150. Thus, the plurality of holes 240 to expose the upper land 214a of the substrate 210 may be formed by radiating the laser beam Lr of the infrared ray area band to repeatedly drill through the molding material 230 at various positions. The drilling position of the laser beam Lr may be controlled by the first galvanometer scanner 140a (as illustrated in FIG. 6).

The laser beam Lv of the visible ray area band passing through the telecentric lens 150 may cut through both the molding material 230 and the substrate 210 to form a plurality of semiconductor packages 200. The cutting direction of the laser beam Lv may be controlled by the second galvanometer 140b (as illustrated in FIG. 6).

The molding material 230 may be scanned with the laser beam Lr of the infrared ray area band in a circle or spiral shape to form the plurality of holes 240, and the molding material 230 and the substrate 210 may be scanned with the laser beam Lv of the visible ray area band in a line or trench shape to cut the substrate 210 into the plurality of semiconductor packages 200. However, the shapes of the plurality of holes and the plurality of semiconductor packages 200 are not limited thereto and either may be formed in other shapes.

The laser beam Lr of the infrared ray area band and the laser beam Lv of the visible ray area band may be radiated to the top surface of the semiconductor package 200 at the same time. In one exemplary embodiment, the incidence of the laser beam Lv of the visible ray area band and the laser beam Lr of the infrared ray area band may be processed in about two to three minutes, respectively, and the individual semiconductor package 200 separated through the cutting process may be transferred to a package visual inspection apparatus.

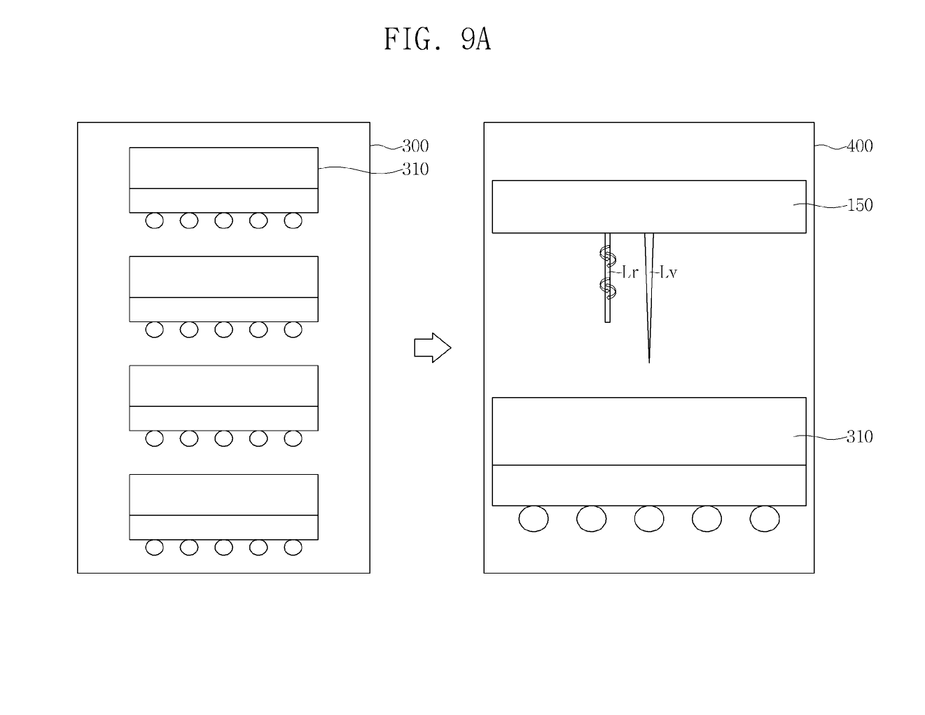

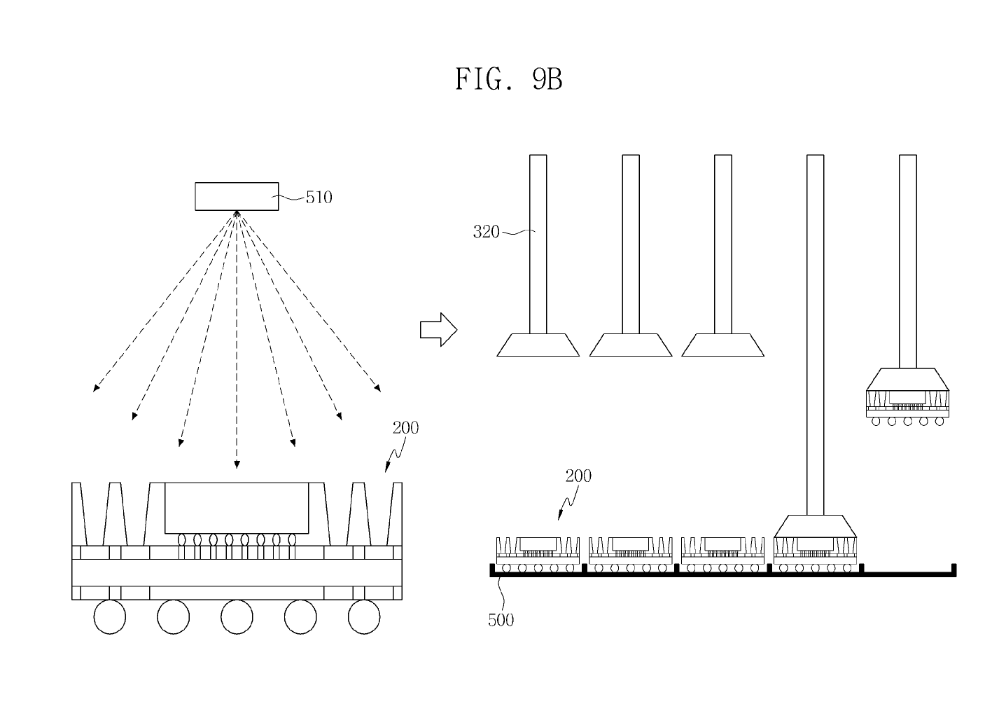

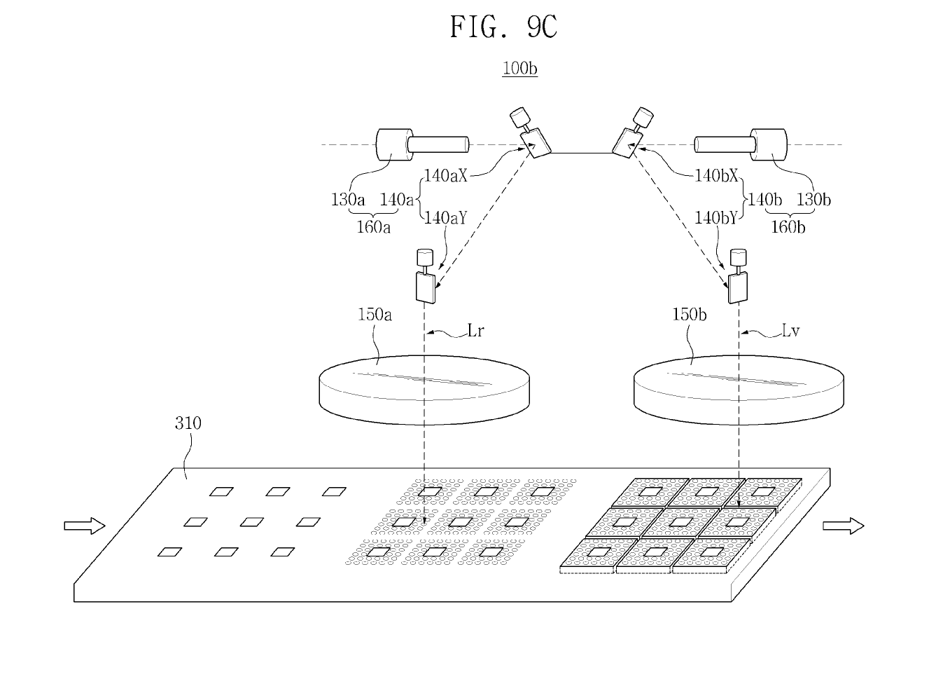

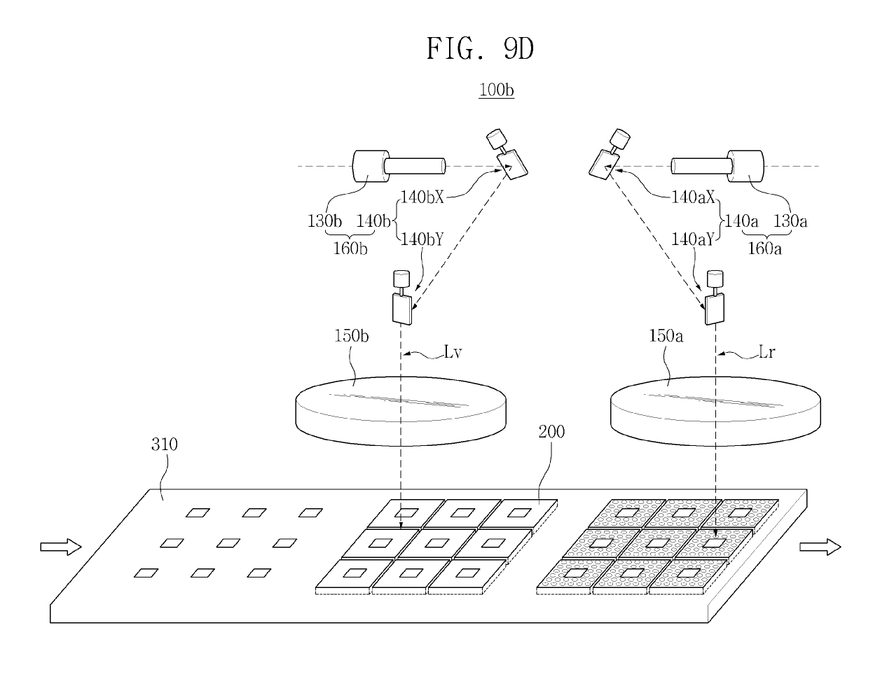

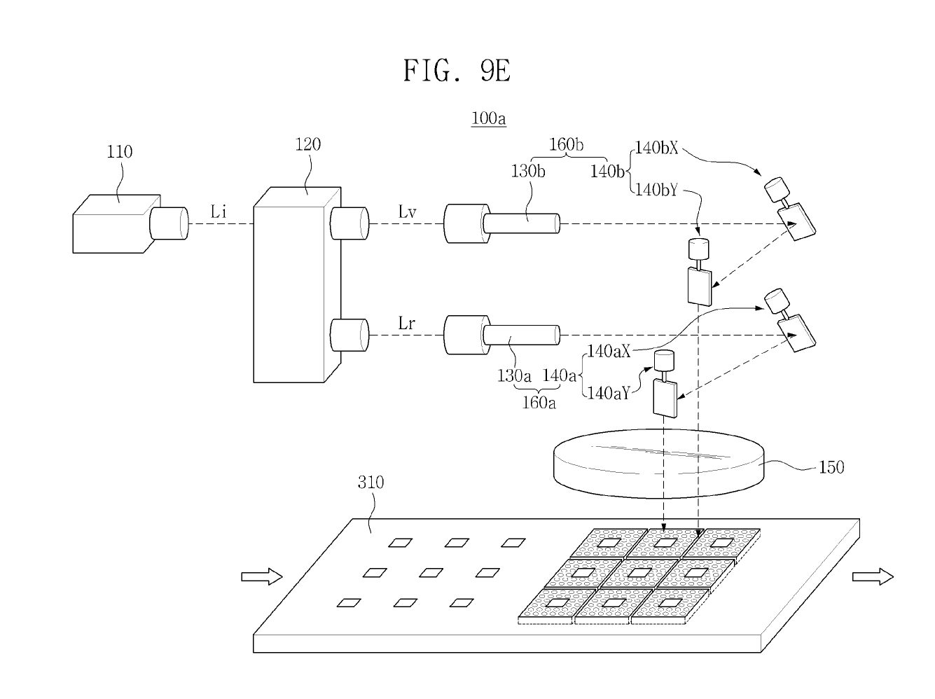

FIG. 9A to FIG. 9E are views illustrating a drilling process and a cutting process using the semiconductor processing apparatuses 100a or 100b by means of a laser according to an exemplary embodiment of the present general inventive concept.

Referring to FIG. 9A, a PCB strip 310 may be seated on a magazine loader 300 and thereby be able to perform two-dimensional product information inspection. The two-dimensional product information inspection may provide information on a determination as to whether the PCB strip 310 passes or fails, and information on points at which the laser drilling and the cutting processes should be performed.

The PCB strip 310 for which the two-dimensional product information inspection is performed may be moved to a stage 400 on which the semiconductor processing apparatus 100a is disposed. The PCB strip 310 may be disposed beneath a telecentric lens 150 of the semiconductor processing apparatus. On the stage 400, the processes described with reference to FIG. 8 may be performed. For example, the PCB strip 310 may be drilled by laser beam Lr and cut by laser beam Lv to be separated into the plurality of semiconductor packages 200.

Referring to FIG. 9B, the semiconductor package 200 may be cleaned. The cleaning process may be cleaned with ultrasonic waves and air. The ultrasonic wave cleaning can remove foreign materials attached to the semiconductor package 200 using an ultrasonic washer 510. The cleaned individual semiconductor packages 200 can be determined to pass or fail in a three-dimensional package visual inspection apparatus. The semiconductor package 200 for which the three-dimensional package visual inspection has been completed can be sorted and then safely seated on a tray 500 by a picker 320.

FIG. 9C is a view illustrating the consecutive drilling process and cutting process using the semiconductor processing apparatus 100b according to an exemplary embodiment of the present general inventive concept.

Referring to FIG. 9C, when the PCB strip 310 enters the semiconductor processing apparatus 100b, the drilling process may be performed using the first laser beam irradiation unit 160a, and subsequently the cutting process using the second laser beam irradiation unit 160b may be consecutively performed.

Referring to FIG. 1A and FIG. 1B, the drilling process may include forming the plurality of holes 240 of FIG. 8 on the PCB strip 310 using the laser beam Lr of the infrared ray area band. The cutting process may include cutting the PCB strip 310 to form semiconductor packages 200 using the laser beam Lv of the visible ray area band.

The laser beam Lr of the infrared ray area band having a wavelength of, for example, 1064 nm, may not penetrate the substrate 210 since a rate reflected from a metal surface is high. While performing the drilling process, the surface of the PCB strip 310 may be scanned with the laser beam Lr of the infrared ray area band in a circular shape or a spiral shape. A scanning speed of the drilling process and/or the cutting process may be 300 to 1200 mm/sec. When the scanning speed is less than 300 mm/sec, a process time is delayed and thus a productivity yield of the semiconductor package 200 may be lowered, and when the scanning speed exceeds 1200 mm/sec, the drilling may not be completed and thus the upper land 214a may not be exposed.

The laser beam Lv of the visible ray area band having the wavelength of, for example, 532 nm, may penetrate both the molding material 230 and the substrate 210, and thus cut the PCB strip 310. The laser beam Lv of the visible ray area band is able to precisely perform the processing of sides of the molding material 230 and sides of the substrate 210 so that a surface perpendicular to the top surface of the substrate 210 is exposed. While performing the cutting process, the surface of the PCB strip 310 may be scanned with the laser beam Lv of the visible ray area band in a straight line shape. The drilling process and/or the cutting process may be controlled with the scanning speed and the power of the respective laser beam (Lr, Lv). The power required for the drilling process and/or cutting process may be 5 to 30 W. When the power is less than 5 W, it is difficult to obtain an energy density of a degree to which the processing of the substrate 210 can be performed at a spot position of the laser beams Lv and Lr, and when the power exceeds 30 W, there is a problem in that it is non-economical since the energy consumption increases.

The cutting process may include irradiating and scanning the same position with the laser beam Lv of the visible ray area band several times and forming a plurality of holes or grooves on the PCB strip 310.

The laser beams Lr and Lv may have a frequency of 20 to 60 kHz. When the frequency is less than 20 kHz, although processing of the semiconductor package 200 can be improved, productivity is lowered due to a large consumption time. When the frequency exceeds 60 kHz, the cutting process may be insufficient, therefore the cut surface may not be clearly formed, or the drilling process may not complete, thus the upper land 214a of the substrate 210 may not be exposed.

FIG. 9D is a view illustrating the cutting process using the second laser beam irradiation unit 160b and drilling process using the first laser beam irradiation unit 160a, using the semiconductor processing apparatus 100b according to another exemplary embodiment of the present general inventive concept.

Referring to FIG. 9D, when the PCB strip 310 enters the semiconductor processing apparatus 100b, the cutting process may be performed, and subsequently the drilling process may be performed.

Referring to FIG. 1A and FIG. 1B, the drilling process may include forming the plurality of holes 240 (of FIG. 8) on the PCB strip 310 using the laser beam Lr of the infrared ray area band. The cutting process may include cutting the PCB strip 310 using the laser beam Lv of visible ray area band.

FIG. 9E is a view illustrating performing the cutting process and the drilling process at the same time using a semiconductor processing apparatus 100a according to an exemplary embodiment of the present general inventive concept.

Referring to FIG. 9E, when the PCB strip 310 enters the semiconductor processing apparatus 100a, the drilling process using the first laser beam irradiation unit 160a and the cutting process using the second laser beam irradiation unit 160b may be performed at the same time. For example, the laser beams Lr and Lv having different wavelengths may pass through one telecentric lens 150 and then cut and drill the PCB strip 310.

In accordance with various exemplary embodiments of the present general inventive concept, a drilling process of exposing a top land covered by an epoxy molding compound (EMC) and a cutting process of individualizing a semiconductor package are performed at the same time, and thereby a production process operation time of the stacked semiconductor package can be reduced.

In accordance with various exemplary embodiments of the present general inventive concept, the laser drilling process and the laser sawing process may be implemented through one apparatus, and accordingly productivity may be increased and process maintenance infra costs may be decreased, and thus competitiveness such as assembly cost reduction can be enhanced.

The foregoing is illustrative of embodiments and is not to be construed as limiting thereof. Although a few embodiments of the present general inventive concept have been described, those skilled in the art will readily appreciate that many modifications are possible in embodiments without materially departing from the principles and spirit of the general inventive concept. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims.

What is claimed is:

1. A semiconductor processing apparatus, comprising:
a first laser beam irradiation unit including a first variable beam expanding telescope and a first galvanometer scanner transferring a first laser beam having a first wavelength;
a second laser beam irradiation unit including a second variable beam expanding telescope and a second galvanometer scanner transferring a second laser beam having a second wavelength; and
a telecentric lens.

2. The semiconductor processing apparatus according to claim 1, wherein the telecentric lens includes:
a first telecentric lens configured to receive the first laser beam from the first laser beam irradiation unit; and
a second telecentric lens configured to receive the second laser beam from the second laser beam irradiation unit.

3. The semiconductor processing apparatus according to claim 2, wherein the first telecentric lens and the second telecentric lens each include a diameter aperture, a concave lens, an aspherical lens, and a convex lens.

4. The semiconductor processing apparatus according to claim 1, wherein the first laser beam has a wavelength of an infrared ray area band.

5. The semiconductor processing apparatus according to claim 1, wherein the second laser beam has a wavelength of a visible ray area band.

6. The semiconductor processing apparatus according to claim 1, wherein the first galvanometer scanner includes:
a first X-direction galvanometer scanner configured to scan with the first laser beam in an X-direction; and
a first Y-direction galvanometer scanner configured to scan with the first laser beam in a Y-direction.

7. The semiconductor processing apparatus according to claim 6, wherein the second galvanometer scanner includes:
a second X-direction galvanometer scanner configured to scan with the second laser beam in the X-direction and a second Y-direction galvanometer scanner configured to scan with the second laser beam in the Y-direction.

8. The semiconductor processing apparatus according to claim 1, wherein the first galvanometer scanner scans with the first laser beam in a circle or spiral shape.

9. The semiconductor processing apparatus according to claim 1, wherein the second galvanometer scanner scans with the second laser beam in a line shape.

10. The semiconductor processing apparatus according to claim 1, further comprising:
a laser oscillator configured to generate an initial laser beam; and
a laser wavelength converter configured to separate the initial laser beam into the first laser beam and the second laser beam.

11. The semiconductor processing apparatus according to claim 10, wherein one of the first laser beam and the second laser beam has the same wavelength as the initial laser beam.

12. The semiconductor processing apparatus according to claim 1, wherein the first variable beam expanding telescope and second variable beam expanding telescope each include a divergence lens and a convergence lens, respectively.

13. A semiconductor processing method, comprising:
generating a laser beam having a visible ray area band and a laser beam having an infrared ray area band;
expanding spot diameters of the laser beams; and
moving the laser beam having the visible ray area band linearly to cut a semiconductor substrate and moving the laser beam having the infrared ray area band rotationally to drill holes in a molding material on the semiconductor substrate without penetrating the semiconductor substrate, thereby performing a cutting process with the laser beam having the visible ray area band and performing a drilling process with the laser beam having the infrared ray area band,
wherein the cutting process and the drilling process are performed at the same time.

14. The semiconductor processing method according to claim 13, wherein the laser beam having the visible ray area band and the laser beam having the infrared ray area band are radiated in parallel to optical axes thereof.

15. The semiconductor processing method according to claim 14, wherein the laser beam having the visible ray area band has a wavelength of about 532 nm and the laser beam having the infrared ray area band has a wavelength of about 1064 nm.

16. A semiconductor processing apparatus, comprising:
a first laser beam irradiation unit configured to control a spot position of a first laser beam having a first wavelength;
a second laser beam irradiation unit configured to control a spot position of a second laser beam having a second wavelength; and
at least one telecentric lens configured to control travel directions of the first and second laser beams to be parallel to optical axes of the first and second laser beams.

17. The semiconductor processing apparatus of claim 16, wherein the first and second irradiation units each comprise at least two galvanometer scanners configured to move the respective spot positions of the first and second laser beams in at least two directions.

18. The semiconductor processing apparatus of claim 16, wherein the at least one telecentric lens comprises a first telecentric lens configured to control the travel directions of the first laser beam and a second telecentric lens configured to control the travel direction of the second laser beam.

19. The semiconductor processing apparatus of claim 16, wherein the first and second irradiation units include a first and second variable beam expanding telescope, respectively, configured to control a spot diameter size of the first and second laser beams.
